(19) United States
(12) Patent Application Publication
(10) Pub. No.: US 2012/0164356 A1
(43) Pub. Date: Jun. 28, 2012

(54) PROCESS FOR SURFACE TREATING ALUMINUM OR ALUMINUM ALLOY AND ARTICLE MADE WITH SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); XIAO-QING XIONG, Shenzhen City (CN)

(73) Assignees: HON HAI PRECISION INDUSTRY CO., LTD., Tu-Cheng (TW); HONG FU JIN PRECISION INDUSTRY (ShenZhen) CO.,LTD., Shenzhen City (CN)

(21) Appl. No.: 13/170,953

(22) Filed: Jun. 28, 2011

(30) Foreign Application Priority Data
Dec. 24, 2010 (CN) 201010604484.2

(51) Int. Cl. B32B 15/04; C23C 14/35; B32B 7/02; C23C 14/06

(52) U.S. Cl. 428/34.1; 204/192.15; 428/469; 428/323; 428/336

(57) ABSTRACT

A method for surface treating aluminum or aluminum alloy, the method comprising the following steps of: providing a substrate made of aluminum or aluminum alloy; forming a TiON coating on the substrate by magnetron sputtering, using aluminum as a target, and nitrogen and oxygen as reactive gases; and forming a chromium oxynitride coating on the TiON coating by magnetron sputtering, using chromium as a target, and nitrogen and oxygen as reactive gases.

### CROSS-REFERENCE TO RELATED APPLICATIONS

This application is related to co-pending U.S. patent applications (Attorney Docket No. US35132, US35134), each entitled “PROCESS FOR SURFACE TREATING ALUMINUM OR ALUMINUM ALLOY AND ARTICLE MADE WITH SAME”, by Chang et al. These applications have the same assignee as the present application. The above-identified applications are incorporated herein by reference.

### BACKGROUND

1. Technical Field

The disclosure generally relates to processes for surface treating aluminum or aluminum alloy and articles made of aluminum or aluminum alloy treated by the process.

2. Description of Related Art

Due to having many good properties such as light weight and quick heat dissipation, aluminum and aluminum alloy are widely used in manufacturing components (such as housings) of electronic devices. However, aluminum and aluminum alloy have a lower erosion resistance.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary process for surface treating aluminum or aluminum alloy and articles made of aluminum or aluminum alloy treated by the process. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary article treated by the present process.

FIG. 2 is a schematic view of a magnetron sputtering machine for processing the article in FIG. 1.

### DETAILED DESCRIPTION

An exemplary process for surface treating aluminum or aluminum alloy may include the following steps.

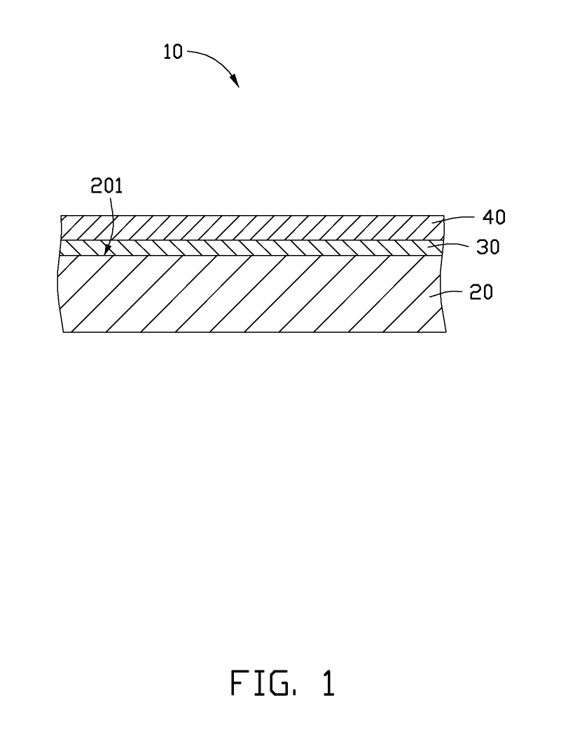

Referring to FIG. 1, a substrate 20 is provided. The substrate 20 is made of aluminum or aluminum alloy.

The substrate 20 is pretreated. For example, the substrate 20 is ultrasonically cleaned with a solution (e.g., alcohol or Acetone) in an ultrasonic cleaner, to remove impurities such as grease or dirt from the substrate 20. Then, the substrate is dried.

An aluminum oxynitride (AlON) coating 30 and a chromium oxynitride (CrON) coating 40 are formed on the substrate 20 by magnetron sputtering. The AlON coating 30 is directly formed on a surface 201 of the substrate 20. The CrON coating 40 is directly formed on the AlON coating 30. The AlON coating 30 has close physical properties (such as thermal expansion coefficient) to the substrate 20, thus the AlON coating 30 can improve the bonding of the substrate 20 and the CrON coating 40. The magnetron sputtering for depositing the AlON coating 30 and the CrON coating 40 may be performed by the following steps.

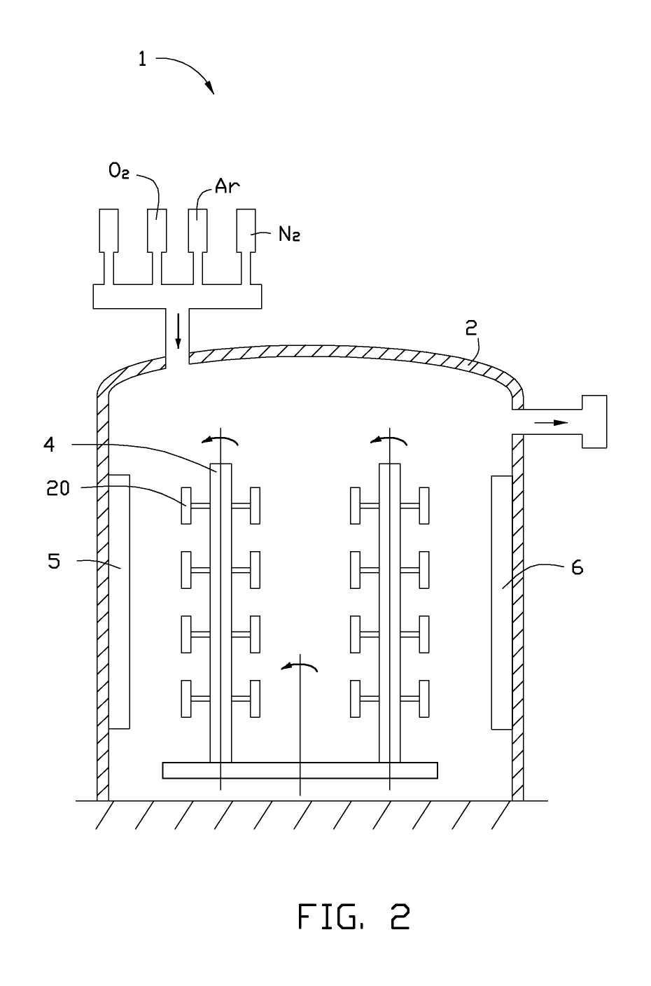

First, the AlON coating 30 is directly deposited on the substrate 20 by magnetron sputtering. The substrate 20 is held by a rotating bracket 14 in a vacuum chamber 12 of a magnetron sputtering machine 1 as shown in FIG. 2. The vacuum chamber 2 maintains an internal pressure of about 6×10⁻³ Pa to about 8×10⁻³ Pa. The temperature in the vacuum chamber 2 is maintained at a temperature of about 100° C. to about 150° C. The speed of the rotating bracket 4 is in a range from about 0.5 revolutions per minute (rpm) to about 1 rpm. Argon, oxygen, and nitrogen are simultaneously supplied into the vacuum chamber 12, with the argon as a sputtering gas, and the oxygen and nitrogen as reactive gases. The flux of the argon is from about 150 Standard Cubic Centimeters per Minute (sccm) to about 300 sccm. The flux of the oxygen is in a range from about 30 to about 60 sccm, and the flux of the nitrogen is in a range from about 15 to about 40 sccm. A bias voltage is applied to the substrate 20 in a range from about −100 volts (V) to about −300V. At least one aluminum target 5 is evaporated at a power of about 6 kW to about 12 kW for about 0.5 hours to about 1 hour, to deposit the AlON coating 30 on the substrate 20. The power may be a medium-frequency AC power.

Then the CrON coating 40 is directly formed on the AlON coating 30 by magnetron sputtering. This step may be carried out in the magnetron sputtering machine 1. The aluminum targets 5 are switched off. The flux of the oxygen is adjusted in a range of about 40 sccm to about 100 sccm and the flux of the nitrogen is adjusted in a range of about 30 sccm to about 60 sccm. At least one chromium target 6 is evaporated at a power of about 8 kW to about 10 kW for about 0.5 h to about 2 h, depositing the CrON coating 40 on the AlON coating 30 with the remaining conditions maintained same with depositing the AlON coating 30.

FIG. 1 shows a cross-section of a portion of an exemplary article 10 made of aluminum or aluminum alloy processed by the surface treating as described above. The article 10 may be housings for electronic devices, such as mobile phones. The article 10 includes the substrate 20 made of aluminum or aluminum alloy, the AlON coating 30 formed on the substrate 20, and the CrON coating 40 formed on the AlON coating 30. In the AlON coating 30, the atomic percentage of Al is about 40% to about 65%; the atomic percentage of O is about 25% to about 50%; the atomic percentage of N is about 10% to about 20%. In the CrON coating 40, the atomic percentage of Cr is about 50% to about 70%; the atomic percentage of O is about 20% to about 45%; the atomic percentage of N is about 5% to about 10%. The thickness of the AlON coating 30 may be about 0.4 μm to about 0.8 μm. The thickness of the CrON coating 40 may be about 0.5 μm to about 2.0 μm. The CrON coating 40 formed by this exemplary method comprises crystal grains having an average particle diameter of about 4 nm to about 7 nm. Crystal grains having an average diameter of about 4 nm to about 7 nm have smaller spaces between crystal grains than in materials have larger average particle diameters. Thus, the CrON coating 40 has improved compact density and the article 10 coated with the CrON coating 40 has improved erosion resistance since it becomes harder for contaminants to enter the spaces between the crystal grains.

### EXAMPLES

Experimental examples of the present disclosure are described as follows.

### Example 1

A sample of aluminum alloy substrate was ultrasonically cleaned for about 30 minutes and then was placed into the vacuum chamber 2 of the magnetron sputtering machine 1. The vacuum chamber 2 was evacuated to maintain an internal pressure of about 8×10⁻³ Pa and was heated to maintain a temperature of about 120° C. The speed of the rotating bracket 4 was about 0.5 rpm. Argon, oxygen, and nitrogen were simultaneously fed into the vacuum chamber 2. The flux of the argon was about 150 sccm. The flux of the oxygen was about 20 sccm, and the flux of the nitrogen was about 15 sccm. The bias voltage applied to the substrate was about −200V. Aluminum targets were evaporated at a power of about 8 kw with the duty cycle of about 50% for about 0.5 h, depositing a AlON coating on the substrate. Then the aluminum targets were switched off. The flux of the oxygen was adjusted to 40 sccm. The flux of the nitrogen was adjusted to 30 sccm. chromium targets were evaporated at a power of about 8 kW with the duty cycle of about 50% for about 1 h, depositing a CrON coating on the AlON coating with the remaining parameters were unchanged.

### Example 2

Unlike the example 1, in the example 2, the flux of the oxygen was about 30 sccm, and the flux of the nitrogen was about 20 sccm during sputtering the AlON coating. The flux of the oxygen was about 80 sccm, and the flux of the nitrogen was about 50 sccm during sputtering the CrON coating. Except the above difference, the remaining experiment conditions of example 2 were same with example 1. An article of aluminum alloy coated with an AlON coating and a CrON coating was obtained according to example 2.

The samples processed in example 1 and 2 have similar microcosmic configuration and surface topography, so have similar erosion resistance.

### Comparison Example

A sample of aluminum alloy substrate was processed by magnetron sputtering in the magnetron sputtering machine 1. Unlike the example 1, the target material was chromium and the reactive gas was nitrogen in the comparison example. The flux of the nitrogen was about 50 sccm. The bias voltage applied to the substrate was about −200V. The chromium targets were evaporated at a power of about 8 kW with the duty cycle of about 50% for about 0.5 h. Except for the above differences, the remaining experiment conditions of the comparison example were same as example 1. A chromium nitride (CrN) coating was deposited on the aluminum alloy substrate.

### Results of the Above Examples

An neutral salt spray test was implemented to the samples coated with the AlON coating and the CrON coating and the sample coated with CrN coating. The test conditions included 5% NaCl (similar to salt-fog chloride levels), that was neutral at 35° C. to simulate condensing gases with moisture and salt. The test was an accelerated corrosion test for assessing coating performance. Obvious erosion was observed with the sample coated with CrN coating after about 4 h. However, after about 72 h, erosion began to be observed the samples coated with the AlON coating and the CrON coating.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method for surface treating aluminum or aluminum alloy, the method comprising the following steps of:
providing a substrate made of aluminum or aluminum alloy;
forming an aluminum oxynitride coating on a surface of the substrate by magnetron sputtering, using aluminum as a target, and nitrogen and oxygen as reactive gases; and
forming a chromium oxynitride coating on the aluminum oxynitride coating by magnetron sputtering, using chromium as a target, and nitrogen and oxygen as reactive gases.

2. The method as claimed in claim 1, wherein during magnetron sputtering the Aluminum oxynitride coating, the flux of the oxygen is about 30 sccm to about 60 sccm, the flux of the nitrogen is about 15 sccm to about 40 sccm.

3. The method as claimed in claim 2, wherein during magnetron sputtering the Aluminum oxynitride coating, the substrate is placed in a vacuum chamber of a magnetron sputtering machine; the vacuum chamber maintains an internal pressure of about 6×10⁻³ Pa to about 8×10⁻³ Pa and a temperature of about 100° C. to about 150° C.; argon, the oxygen, and the nitrogen are simultaneously supplied into the vacuum chamber, the flux of the argon is in a range from about 150 to about 300 sccm; a bias voltage is applied to the substrate in a range from about −100V to about −300V; the aluminum target is evaporated at a power of about 8 kW to about 10 kW for about 0.5 hours to about 1 hours.

4. The method as claimed in claim 1, wherein during magnetron sputtering chromium oxynitride coating, the flux of the oxygen is about 40 sccm to about 100 sccm, the flux of the nitrogen is about 30 sccm to about 60 sccm.

5. The method as claimed in claim 4, wherein during magnetron sputtering the chromium oxynitride layer, the substrate is placed in a vacuum chamber of a magnetron sputtering machine; the vacuum chamber maintains an internal pressure of about 6×10⁻³ Pa to about 8×10⁻³ Pa and a temperature of about 100° C. to about 150° C.; argon, the oxygen, and the nitrogen are simultaneously supplied into the vacuum chamber, the flux of the argon is in a range from about 150 to about 300 sccm; a bias voltage is applied to the substrate in a range from about −100V to about −300V; the chromium target is evaporated at a power of about 8 kW to about 10 kW for about 0.5 hours to about 2 hours.

6. The method as claimed in claim 1, wherein the aluminum oxynitride coating comprises, about 40% to about 65% of atomic Al; about 25% to about 50% of atomic O; about 10% to about 20% of atomic N.

7. The method as claimed in claim 1, wherein the chromium oxynitride coating comprises, about 50% to about 70% of atomic Cr; about 20% to about 45% of atomic O; about 5% to about 10% of atomic N.

8. The method as claimed in claim 1, wherein the chromium oxynitride coating is composed of crystal grains having an average particle diameter of about 4 nm to about 7 nm.

9. An article, comprising:
a substrate made of aluminum or aluminum alloy;
an aluminum oxynitride coating formed on a surface of the substrate; and
a chromium oxynitride coating formed on the aluminum oxynitride coating.

10. The article as claimed in claim 9, wherein the aluminum oxynitride coating comprises, about 40% to about 65% of atomic Al; about 25% to about 50% of atomic O; about 10% to about 20% of atomic N.

11. The article as claimed in claim 9, wherein the chromium oxynitride coating comprises, about 50% to about 70% of atomic Cr; about 20% to about 45% of atomic O; about 5% to about 10% of atomic N.

12. The article as claimed in claim 9, wherein the chromium oxynitride coating is composed of crystal grains having an average particle diameter of about 4 nm to about 7 nm.

13. The article as claimed in claim 9, wherein the thickness of the aluminum oxynitride coating is about 0.4 μm to about 0.8 μm.

14. The article as claimed in claim 9, wherein the thickness of the thickness of the chromium oxynitride coating is about 0.5 μm to about 2.0 μm.

15. The article as claimed in claim 9, wherein the aluminum oxynitride coating and the chromium oxynitride coating are formed by magnetron sputtering.

16. The article as claimed in claim 9, wherein the article is a housing of electronic devices.
